(19) United States
(12) Patent Application Publication
(10) Pub. No.: US 2018/0331682 A1
(43) Pub. Date: Nov. 15, 2018

(54) Gate Driver for Depletion-Mode Transistors

(71) Applicant: Sarda Technologies, Inc., Durham, NC (US)

(72) Inventors: Bogdan M. Duduman, Raleigh, NC (US); John K. Fogg, Cary, NC (US)

(21) Appl. No.: 16/043,188

(22) Filed: Jul. 24, 2018

Related U.S. Application Data
(63) Continuation-in-part of application No. 15/716,265, filed on Sep. 26, 2017.
Application No. 15/716,265 is a continuation of application No. 15/190,095, filed on Jun. 22, 2016, now Pat. No. 9,774,322.

(51) Int. Cl. H03K 17/22; H03K 7/08; H03K 17/06; H02M 3/07; H03K 5/19

(52) U.S. Cl. CPC H03K 17/223; H03K 7/08; H03K 2017/066; H02M 3/07; H03K 5/19; H03K 17/063

(57) ABSTRACT

The present disclosure presents a circuit, method, and system for dynamically determining optimal deadtime values in a DC-DC converter power stage while operating the circuit under controlled conditions during a test/trim routine. The determined optimal deadtime values are stored in non-volatile memory. The optimal deadtime values are used as fixed settings during normal PWM operation. On start-up, the optimal, fixed deadtime values are loaded into the deadtime circuits of the driver and used during normal PWM operation of the DC-DC converter power stage circuit.

### CROSS-REFERENCE TO RELATED APPLICATIONS

This Non-Provisional patent Application is a continuation in part of, and claims priority benefit of, U.S. patent application Ser. No. 15/716,265, filed Sep. 26, 2017, entitled “Gate Driver for Depletion-Mode Transistors,” which in turn is a continuation of, and claims priority benefit of, U.S. patent application Ser. No. 15/190,095 (Now U.S. Pat. No. 9,774,322), filed Jun. 22, 2016, entitled “Gate Driver for Depletion-Mode Transistors.” The aforementioned disclosure is hereby incorporated by reference herein in its entirety including all references cited therein.

### FIELD OF THE INVENTION

The present invention relates to semiconductor devices, and more specifically to gate driver circuits for depletion-mode Field Effect Transistors (FETs).

### BACKGROUND

A DC-DC converter circuit is a type of switching circuit that regulates an output voltage from a given input voltage. The circuit may step-up (e.g. Boost converter) or step-down (e.g. Buck converter) the voltage. Switching circuits come in two varieties, standard and synchronous. FIG. 1A illustrates a prior art standard Buck DC-DC converter circuit 100. Standard Buck converters use a control switching transistor 102 to regulate voltage and current flow in the upper side, while a diode 104 is used for the lower side of the circuit. A periodic signal, such as a Pulse Width Modulated (PWM) signal exhibiting a duty cycle (D), allows control and regulation of the output voltage by exercising the control switch in accordance with the duty cycle of the PWM signal. The duty cycle represents the fraction of a switching period during which the control switching transistor 102 is turned on. The output voltage (VOUT) 120 is directly proportional to the product of the input voltage (VIN) 108 and the duty cycle (D). A driver 116 alternately switches the upper-side transistor 102 on and off in step with the PWM signal, thereby regulating the time-averaged voltage at the switching node 106. A forward biased diode 104, facilitates the continuous flow of inductor current when the control transistor 102 is switched off. The diode 104 is customarily referred to as a “freewheeling diode”, since it circulates positive output inductor 110 current flow (flowing toward VOUT 120) while the control switching transistor 102 is in an off state. The combination of the transistor 102 and diode 104, in response to the PWM signal, operate to regulate the voltage level VOUT 120 across the load, R_{L} 114. A voltage source provides input voltage at VIN 108. The switching node 106 between the control switch 102 and the freewheeling diode 104 is connected to the converter's output through a low-pass filter comprising an inductor 110 and an output capacitor 112. VOUT 120 is referenced to ground 118.

FIG. 1B illustrates a prior art synchronous DC-DC converter circuit 122. This type of converter circuit 122 uses a half-bridge switch configuration, and therefore has two switching transistors, which are known as the upper-side (or control) transistor 102 and the lower-side (or synchronous) transistor 124. The two transistors are actively controlled to alternately switch on and off out of phase with each other, regulating the output voltage VOUT 120. A voltage source provides input voltage at VIN 108. The switching node 106 between the two devices is connected to the converter's output through a low-pass filter comprising an output inductor 110 and an output capacitor 112. VOUT 120 is referenced to ground 118. A driver 116 provides on/off control for the switching transistors 102 and 124, in response to a periodic control signal such as a PWM signal.

The transistor switches can be fabricated as either enhancement-mode (E-mode) devices, which are off-state at zero applied gate bias, or depletion-mode (D-mode) devices, which are on-state at zero applied gate bias.

Silicon (Si) based voltage converters typically use enhancement mode MOSFETs for the transistor switches 102, and 124, and for drivers. A Gallium-Arsenide (GaAs) depletion mode power FET transistor is also a 3-terminal device. There is a channel running between drain (D) and source (S), whose conduction is controlled by the gate (G) potential. The gate-to-source (or gate-to-drain) junction V-I characteristics resemble very much that of a diode junction, ranging from a Schottky to a high-threshold P-N diode. A N-channel depletion mode FET has a negative threshold for D-S conduction and is on when no voltage is applied to the gate, turning off when a bias more negative than its threshold is applied gate to source (G-S). As the G-S bias increases above the threshold voltage, the D-S channel resistance decreases in proportion to the increase in bias differential. G-S bias is ultimately limited in the positive domain by the forward biasing of the G-S junction.

Compound semiconductors, such as GaAs III-V materials, offer high frequency transistor switching capabilities, however, their G-S control junctions (some resembling Schottky junctions) can be leakier than doped P-N silicon counterparts. Engineering the control circuits to manage the junction leakage issue in the absence of existing negative bias supplies, is substantially more difficult. Also, synchronous converter circuits built using all D-mode switching transistors may conduct current in an uncontrolled and potentially wasteful and/or damaging fashion upon system start-up, before the control electronics can apply nominal voltages to the transistor gate electrodes.

The need for additional circuit components, design complexity and the normally nonexistent negative bias supplies in typical applications has deterred prior commercialization of D-mode gate drivers.

Some form of dead-time control is desirable in power converters. A fixed deadtime approach builds in a rather large fixed amount of deadtime which results in safe, but not necessarily efficient, operation over the range of applications and parameter variations for the expected combinations of power train components (driver, switches and any associated circuit elements). On the other hand, in a self-adaptive scheme, the deadtime is continuously adjusted during normal operation of the circuit. However, self adaptive schemes also fail to deliver the ideal deadtime under dynamic operation, when output voltage is changed or the output load rapidly varies. This leads to inefficient deadtime settings.

### SUMMARY

A method for adjusting deadtime in a DC-DC converter power stage circuit is presented. The method includes placing the DC-DC converter power stage circuit in test mode; and loading a delay address to a delay circuit that produces a deadtime output from the deadtime circuit greater than a target deadtime. The method further includes placing the DC-DC converter power stage circuit in step mode and stepping through delay addresses to progressively reduce the deadtime output of the deadtime circuit until the deadtime output of the deadtime circuit is less than the target deadtime. The method then includes placing the DC-DC converter power stage circuit in test mode and storing a deadtime value corresponding to the currently loaded delay address in non-volatile memory of the DC-DC converter power stage circuit. The method also includes loading the stored deadtime value to the delay address of the deadtime circuit and initializing a signal to initiate a normal operation mode of the DC-DC converter power stage circuit.

A system for adjusting deadtime of a DC-DC converter power stage circuit is presented that includes a delay circuit coupled to a PWM signal and a lower gate of the DC-DC converter power stage circuit and means for loading an initial delay address to the delay circuit that corresponds to a maximum deadtime output from the delay circuit while operating in test mode. The system further includes; means for progressively decreasing deadtime output from the delay circuit by stepping through delay addresses loaded to the delay circuit while operating in a step mode and means for determining for each progressive loaded deadtime address if the deadtime output of the delay circuit is less than a target deadtime. The system also includes non-volatile memory (NVM) for storing a fixed deadtime value corresponding to the delay address loaded for the deadtime output determined to be less than the target deadtime and means for loading the fixed deadtime value from NVM to the delay circuit for operation in PWM mode.

In various embodiments a deadtime circuit is described that includes an upper delay block coupled to a PWM signal and a tap of the upper delay block coupled to an upper gate driver; a lower leading edge (LE) delay block having a plurality of LE delay taps and coupled to an inverted PWM signal line; a lower LE multiplexer coupled to the plurality of LE delay taps of the lower LE delay block and configured to select one of the plurality of the LE delay taps responsive to a lower LE address for output to a lower LE delay signal line; a lower trailing edge (TE) delay block having a plurality of delay taps and coupled to the inverted PWM signal line; a lower TE multiplexer coupled to the plurality of delay taps of the lower TE delay block and configured to select one of the plurality of the TE delay taps responsive to a lower TE address for output to a lower TE delay signal line. The deadtime circuit also includes a latch, inputs of the latch coupled to the lower LE delay signal line and the lower TE delay signal line, an output coupled to a lower gate driver. The deadtime circuit further includes a deadtime state machine configured to: output a lower LE address to the lower LE multiplexer for selecting a LE delay tap, output a lower TE address to the lower TE multiplexer for selecting a LE delay tap, receive an upper gate drive sense signal from output of the upper gate driver, receive a lower gate drive sense signal from output of the lower gate driver, calculate a LE deadtime based on the upper and lower gate drive sense signals, and increase the LE address if the LE deadtime is greater than a target deadtime, or store the LE address in non-volatile memory the LE deadtime is not greater than the target LE deadtime.

In various embodiments a deadtime adjustment system is described that includes an upper gate driver coupled to a delayed Pulse Width Modulated (PWM) signal and an upper gate of a DC-DC converter power stage circuit; a first adjustable delay circuit coupled to the PWM signal and configured to output a first delayed PWM signal responsive to a first delay address; a second adjustable delay circuit coupled to the PWM signal and configured to output a second delayed PWM signal responsive to a second delay address; and a latch configured to receive the first and second delayed PWM signals and output a lower PWM signal via a lower gate driver to a lower gate of the DC-DC converter power stage circuit. The deadtime adjustment system further includes a deadtime state machine including circuits that include logic programmed to operate in a step mode comprising: applying the first address from a working register to the first adjustable delay circuit, receiving an upper gate drive sense signal derived from the upper gate driver and a lower gate drive sense signal derived from the lower gate driver, measuring a first deadtime using the upper and lower gate drive sense signals, and if the first deadtime is greater than a target first deadtime, increment or decrement the first address in the working register to decrease the first deadtime, and repeat the step mode using the decreased first deadtime, or if the first deadtime is not greater than the target first edge deadtime, store the first address in non-volatile memory (NVM), and exit the step mode. The deadtime state machine of the deadtime adjustment system also includes circuits that include logic programmed to operate in a test mode comprising: receiving values for working registers including an initial first address, an initial second address, a target first edge deadtime, and a target second edge deadtime, and outputting a fixed first address from NVM to the first addressable delay circuit.

### BRIEF DESCRIPTION OF THE DRAWINGS

Certain embodiments of the present technology are illustrated by the accompanying figures. It will be understood that the figures are not necessarily to scale and that details not necessary for an understanding of the technology or that render other details difficult to perceive may be omitted. It will be understood that the technology is not necessarily limited to the particular embodiments illustrated herein.

FIG. 1A illustrates an exemplary standard DC-DC converter power stage and output filter circuit.

FIG. 1B illustrates an exemplary synchronous DC-DC converter power stage and output filter circuit.

FIG. 2 illustrates a DC-DC converter power stage and output filter circuit comprising D-mode switching transistors in accordance with aspects of the technology.

FIG. 3 illustrates a dual phase DC-DC converter power stage circuit comprising D-mode switching transistors in accordance with aspects of the technology.

FIG. 4A is an exemplary timing diagram that illustrates a start-up sequence in accordance with aspects of the technology.

FIG. 4B is an exemplary timing diagram that illustrates finer details of start-up sequence 4A in accordance with aspects of the technology.

FIG. 5 is an exemplary timing diagram that illustrates PWM and SMOD signal processing in accordance with aspects of the technology.

FIG. 6 illustrates an alternative dual phase DC-DC converter power stage circuit comprising deadtime control for switching transistors in accordance with aspects of the technology.

FIG. 7A illustrates a high level diagram of a half-bridge synchronous buck based power switching converter (or power converter) of FIG. 6.

FIG. 7B is an exemplary timing diagram illustrating deadtime associated with a Pulse Width Modulated (PWM) signal applied to a driver of a half-bridge based power switching converter of FIG. 7A.

FIG. 8 illustrates an exemplary deadtime circuit for deadtime testing, trimming, storage, and control for switching transistors of FIG. 6.

FIG. 9 illustrates details for the Deadtime State Machine of FIG. 8.

FIG. 10 illustrates details for delay blocks used in FIG. 8.

FIG. 11 is a flowchart illustrating an exemplary method for selecting a deadtime in accordance with aspects of the technology.

FIG. 12 is a flowchart illustrating an exemplary method for a startup routine in accordance with aspects of the technology.

FIG. 13 is an exemplary timing diagram that illustrates a start-up sequence in accordance with aspects of the technology.

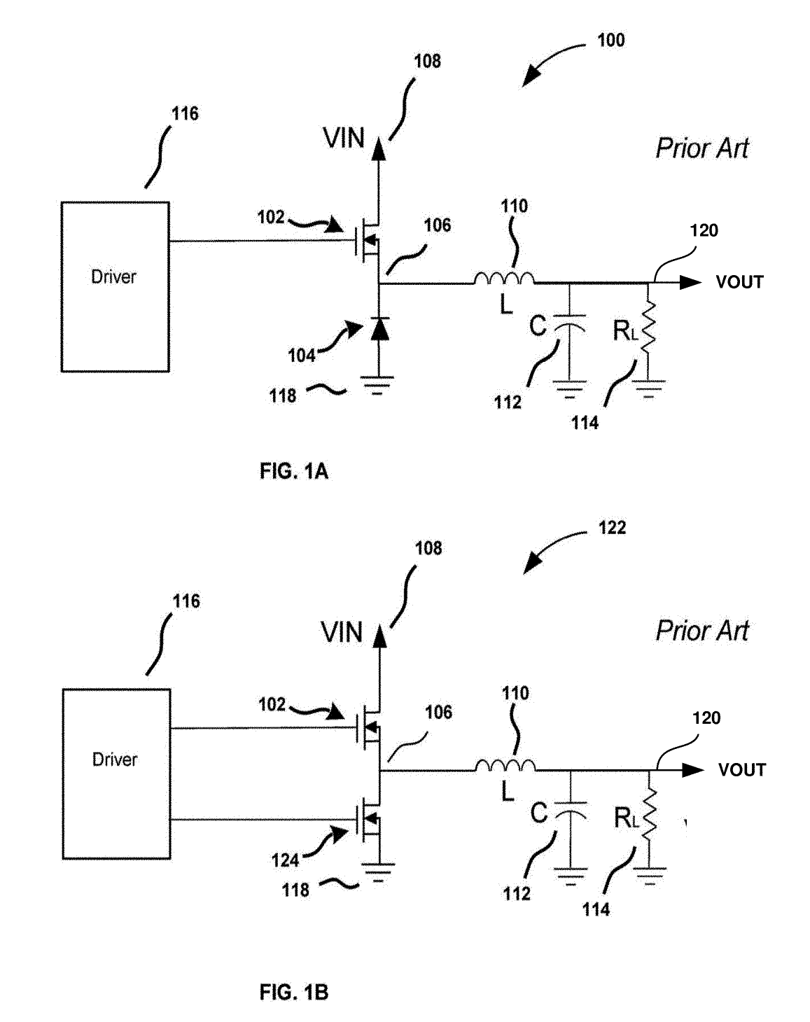

### DETAILED DESCRIPTION

While the disclosed technology is available for embodiment in many different forms, there is shown in the drawings and will herein be described in detail several specific embodiments with the understanding that the present disclosure is to be considered as an exemplification of the principles of the technology and is not intended to limit the technology to the embodiments illustrated.

The terminology used herein is for the purpose of describing particular embodiments only and is not intended to be limiting of the present technology. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used in this specification, the terms “include,” “including,” “for example,” “exemplary,” “e.g.,” and variations thereof, are not intended to be terms of limitation, but rather are intended to be followed by the words “without limitation” or by words with a similar meaning. Definitions in this specification, and all headers, titles and subtitles, are intended to be descriptive and illustrative with the goal of facilitating comprehension, but are not intended to be limiting with respect to the scope of the inventions as recited in the claims. Each such definition is intended to also capture additional equivalent items, technologies or terms that would be known or would become known to a person having ordinary skill in this art as equivalent or otherwise interchangeable with the respective item, technology or term so defined. Unless otherwise required by the context, the verb “may” indicates a possibility that the respective action, step or implementation may be performed or achieved, but is not intended to establish a requirement that such action, step or implementation must be performed or must occur, or that the respective action, step or implementation must be performed or achieved in the exact manner described.

It will be understood that like or analogous elements and/or components, referred to herein, may be identified throughout the drawings with like reference characters. It will be further understood that several of the figures are merely schematic representations of the present technology. As such, some of the components may have been distorted from their actual scale for pictorial clarity.

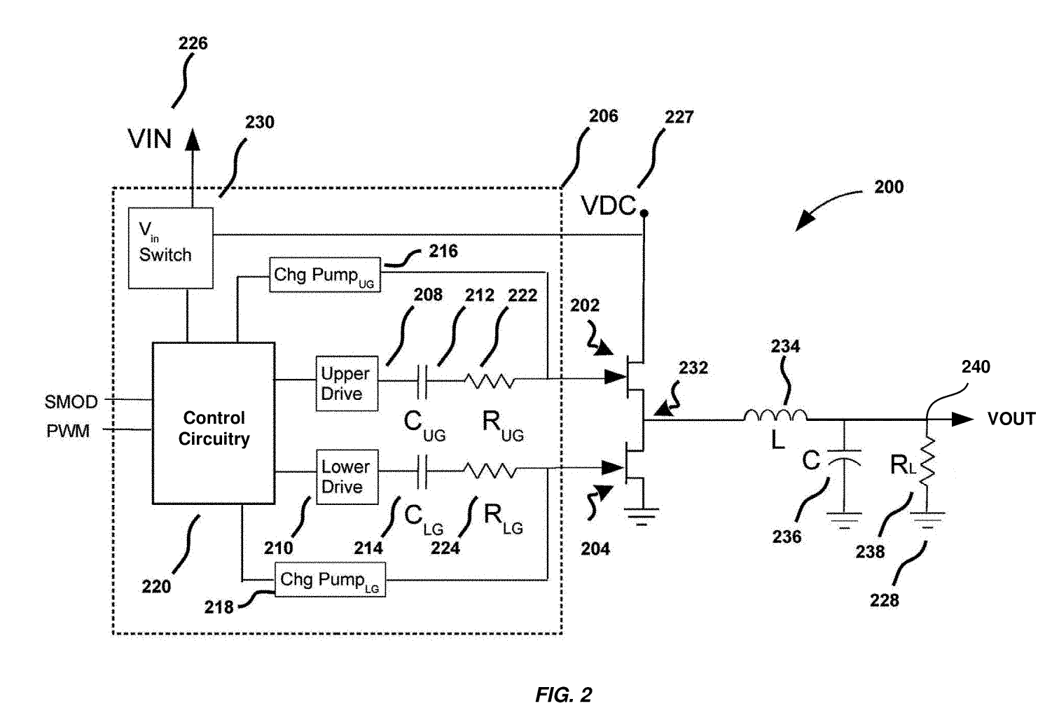

FIG. 2 shows an embodiment of a single phase voltage converter power stage circuit 200. The converter power stage 200 includes a driver for driving PWM signal through a FET module assembly, comprising high-side and low-side transistor switches in a half-bridge synchronous configuration. Either E-mode or D-mode transistors may be implemented using N-channel or P-channel devices. The exemplary embodiments presented herein describe N-channel D-mode FETs. Various embodiments of FIG. 2 use multiple monolithically integrated GaAs compound semiconductor (III-V) D-mode FETs for the switches in a synchronous DC converter. A gFet™ module (see U.S. Pat. No. 8,896,034 B1) is an example of a monolithically integrated GaAs switching circuit.

In various embodiments, a single phase converter 200 includes a pair of FET switches identified as the upper (control) switch 202, and a lower (synch) switch 204, a driver 206, and a low-pass filter. The low-pass filter includes an inductor (L) 234 and a capacitor (C) 236, connected between the switching node 232 and ground 228 of the circuit. The driver 206 includes an upper gate drive circuit 208 and a lower gate drive circuit 210 connected to control circuitry 220. Also included is an upper gate coupling capacitor (C_{UG}) 212 connected between the output of the upper drive 208 and the gate of the upper transistor 202. A lower coupling capacitor (C_{LG}) 214 is connected between the output of the lower drive 210 and the gate of the lower transistor 204. The capacitors, C_{UG} and C_{LG}, are used to level shift the driver outputs from the positive domain into a mostly negative voltage domain, necessary to control the D-mode switches. An upper gate charge pump (Chg Pump_{UG}) 216, and a lower gate charge pump (Chg Pump_{LG}) 218 are connected to the gates of the upper transistor 202 and lower transistor 204, respectively. The charge pumps 216 and 218 are designed to maintain a negative charge on the transistor gates to keep the transistors in an extended off-state when so needed. In some embodiments, the charge pump 216 and 218 may be fully integrated with the gate driver 206. An input voltage switch (VIN Switch) 230 connected between VIN 226 and the upper transistor 202 is also provided to keep current from flowing through the upper transistor prior to the charge pumps 216 and 218 being fully charged. In some embodiments, optional upper (R_{UG}) and lower (R_{LG}) gate resistors 222 and 224 are connected between C_{UG} 212 and C_{LG} 214 and gates of their respective transistor 202 and 204.

In various embodiments, N-channel D-mode FETs require negative voltage to switch between an on-state and an off-state. In those embodiments, C_{UG} 212 and C_{LG} 214 function to voltage shift the gate drive voltage into the negative domain relative to a transistor gate to source (G-S) threshold voltage (V_{gs}_{_}ₜₕ) using AC coupling in lieu of a negative rail.

In some embodiments, all of the driver components may be integrated on a common substrate or various discrete components may be integrated in a package. In various embodiments, the upper and lower gate drive circuits 208 and 210 include at least a portion of the control circuitry 220.

The driver 206 functions to provide switching control of the upper and lower switching transistors 202 and 204 by modulating transistor input power and gate signals. At startup, and prior to receiving PWM signals from a PWM controller, VIN may not be present, and C_{UG} 212 and C_{LG} 214, and charge pumps 216 and 218 may be discharged. Both C_{UG} 212 and C_{LG} 214, and negative charge pumps 216 and 218 must become charged to hold the FETs 202 and 204 in the off-state. The VIN Switch 230 is held off to prevent current from flowing through the upper transistor when VIN 226 is initially supplied because conduction by upper FET 202 or both FETs 202 and 204 simultaneously may overcharge the output and/or overload the circuit. The upper gate drive circuit 208 and lower gate drive circuit 210, controlled by the gate drive controller 220, each drive their respective transistor gates to control the on or off states of the transistor, thereby controlling the output at the switching node 232. In various embodiments, at startup, and with the VIN Switch 230 open, the driver control circuitry 220 issues a series of internally generated (not received from the external PWM controller) PWM signals to “exercise” (i.e. send control signals to them) the gates of the upper and lower transistors 202 and 204. Exercising the transistor gates enables quick charging of capacitors C_{UG} 212 and C_{LG} 214, shortening the time necessary to develop the negative charge required to turn the D-mode switches off, in preparation for closing the input switch and enabling normal operation by means of externally generated PWM signals. Switching the D-mode switches off using charge pumps alone may result in intolerable delay in enabling the circuit for normal operation. Alternatively, the charge pumps may be sized significantly larger, however, doing so may be uneconomical. Charging C_{UG} 212 and C_{LG} 214 by this method prepares the circuit to switch the transistors 202 and 204 on and off by voltage level shifting incoming PWM signals and also allows for turning on the VIN switch. When the charge pumps 216 and 218 are enabled, they work to maintain the negative charge across capacitors C_{UG} 212 and C_{LG} 214 and keep transistors 202 and 204 in an off-state until controlling PWM control signals are received. Keeping the transistors 202 and 204 off renders the circuit available for receiving externally generated PWM signals. The AC coupling capacitors C_{UG} 212 and C_{LG} 214 operate to level shift the drive circuit's Pulse Width Modulation (PWM) outputs to a range of voltages that comply with the corresponding FET switch's G-S threshold voltage (V_{g}_{_}ₜₕ), directing the transistor into an off-state or on-state. Resistors R_{UG} 222 and R_{LG} 224 may optionally be placed between the C_{UG} 212 and C_{LG} 214, and the corresponding gate input of the transistors 202, and 204, to reduce the occurrence of circuit oscillations. These oscillations may occur due to high series parasitic inductance, for example. For example, a typical N-channel D-mode transistor may have a switching threshold of −0.8 Volts. Voltages below the threshold voltage keep the transistor switched off, and voltages above the threshold allow current flow through the transistor. A voltage rail that supplies zero to five (5) volts, for example, is incapable of turning off the transistor, while a properly selected AC coupling capacitor may shift the normally 0 to 5 volt gate-to-source voltage (V_{GS}) of a PWM control signal to a −4.5 V to 0.5 Volt range. This shifted voltage range corresponds with voltages above and below the switching threshold (V_{g}_{_}ₜₕ). A voltage VIN 226 is present, and after transistors 202 and 204 are both driven into an off-state, VIN Switch 230 is closed applying voltage to power the upper transistor 202. Of note is that VIN Switch 230 disconnects VIN 226 from the D-mode switches when it cannot be ensured that the gate drive controller 220 can keep the power switches off or when a fault occurs in a circuit component such that normal operation must be suspended. The charge pumps 216 and 218 continue to maintain the voltage more negative than the threshold, V_{g}_{_}ₜₕ, after the VIN Switch 230 is closed to keep transistors 202 and 204 in the off-state. For example, the charge pumps 216 and 218 maintain a voltage more negative than (lower than) V_{g}_{_}ₜₕ when paired with N-channel D-mode transistors 202 and 204. Thereafter, the charge pumps 216 and 218 may be disabled and incoming PWM control signals may be permitted to modulate the voltage output from the transistor pair 202 and 204 by alternately switching the transistors 202 and 204 on and off according to the duty cycle imposed on the PWM signal. Operation with a normal, periodic PWM input recharges the coupling capacitors 212 and 214, maintaining proper operational negative bias. An output received at the switching node 232 may be low-pass filtered through inductor (L) 234, and a capacitor (C) 236 to produce an output voltage (VOUT) 240 exhibiting minimal ripple across a load, R_{load} 238.

The following equation approximates a minimum value for determining a capacitance value for a coupling capacitor (AC drive capacitor, e.g. coupling capacitor 212 and/or 214) used for voltage shifting a gate drive output.

$${C}_{ac \_ drive} = \frac{{Q}_{g \_ FET}}{{V}_{drive} - {R}_{out \_ driver} \cdot {Q}_{g \_ FET} \cdot 1 / d \cdot {F}_{SW} \cdot {10}^{- 3} - {V}_{f} + {V}_{off}}$$

Where:

C_{ac}_{_}_{drive} is a series AC drive capacitor value in nano-Farads (nF)

Q_{g}_{_}_{FET} is a total gate charge of a FET power transistor being driven, as measured by sweeping a gate-source voltage from V_{f} to V_{off} in a circuit of interest, in nano-Coulombs (nC)

V_{drive} is a magnitude of the gate drive output voltage excursion in Volts (V)

Rₒᵤₜ_{_}_{drive} is the gate drive's output impedance in Ohms ( [symbol] )

d is the duty cycle of the FET power transistor being driven, expressed as a number between 0 and 1

F_{sw} is a switching frequency of the power transistor in megahertz (MHz)

V_{f} is a forward gate-source junction voltage of the power transistor in the ON state, in Volts (this is a positive number)

V_{off} is a desired reverse bias gate-source junction voltage of the power transistor in the OFF state, in Volts (this is a negative number)

The equation shown above may not account for the gate leakage that D-mode transistors may exhibit in the OFF state. In addition, the Rₒᵤₜ_{_}_{drive} term in the denominator may be merely an approximation. Increased accuracy may be obtained with an equation that considers additional parameters. A value that is a few times larger than the minimum necessary value may provide sufficient margin for tolerances and variety in operating conditions.

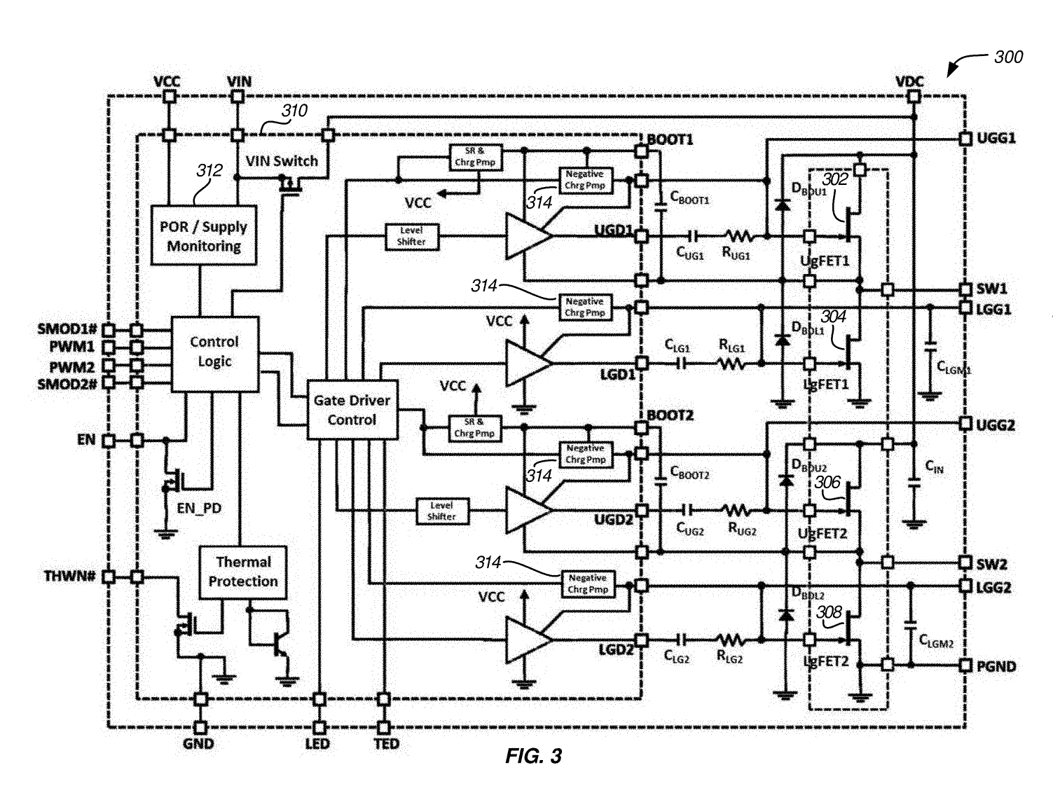

FIG. 3 is a circuit schematic that illustrates an example of a Dual Phase Power Stage circuit 300 for application with D-mode FETs. The dual phase power stage circuit 300 includes a first FET pair comprising upper UgFET1 302 and lower LgFET1 304. The dual phase power stage circuit 300 includes a second FET pair comprising upper UgFET2 306 and lower LgFET2 308. A dual phase driver 310 controls the output of gate signals to the gates of the FET transistors, UgFET1 302, LgFET1 304, UgFET2 306, and LgFET2 308. The dual phase driver 310 outputs may be level shifted using coupling capacitors CUG1, CLG1, CUG2, and CLG2 before being applied to the gates of the respective transistors UgFET1 302, LgFET1 304, UgFET2 306, and LgFET2 308. An output from the FET1 pair (UgFET1 302, LgFET1 304) is applied at terminal SW1. An output from the FET2 pair (UgFET2 306, LgFET2 308) is applied at terminal SW2. The outputs at SW1 and SW2 may be connected to low-pass filters with the voltage applied across one or more resistive loads. Negative Charge Pumps 314 are included to maintain the D-mode FETs off during tri-state, when the FET half-bridge switch circuit (e.g. upper FET1, lower FET1) is not switching and the VIN switch is closed or prior to its closure. The Dual Phase Power Stage circuit 300 includes additional components such as input power supplies monitors and thermal protection circuitry, as described below.

In some embodiments, prior to startup, VCC and VIN may not initially be present, and the coupling capacitors CUG1, CLG1, CUG2, and CLG2 may be discharged. The coupling capacitors C_{UGx} and C_{LGx} become charged when the gates of the switching transistors UgFET1 302, LgFET1 304, UgFET2 306, LgFET2 308 are exercised by the internally generated PWM pulses and the negative charge pumps 314 are enabled to hold the SW nodes in tristate, where both the upper and lower FETs are held in the off-state. When operational, the negative charge pumps 314 may not develop the same negative voltage amplitude across the coupling capacitors CUG1, CLG1, CUG2, and CLG2 as the negative voltage amplitude created by the passing of PWM pulses through the switching transistors UgFET1 302, LgFET1 304, UgFET2 306, LgFET2 308, but it is understood that the amplitude of the voltage developed is sufficiently negative to keep the switching transistors in an off state.

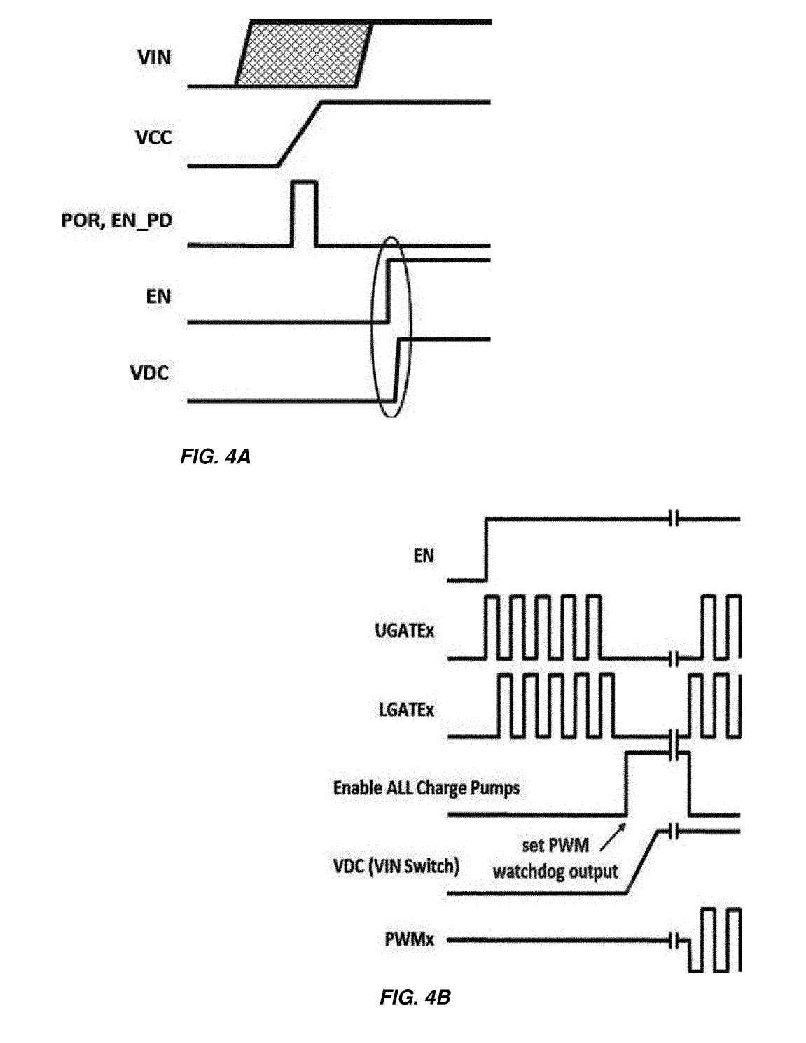

FIG. 4A is an exemplary timing diagram that illustrates a start-up sequence in accordance with aspects of the technology. FIG. 4B is an exemplary timing diagram that illustrates additional details of the start-up sequence of FIG. 4A, in accordance with aspects of the technology. The timing diagram illustrated in FIG. 4A shows a start-up sequence for the converter power stage displayed in FIG. 3 after initiating voltage at the bias supply voltage, VCC, and the power supply voltage, VIN. Once the power supply monitor circuit 312 senses that VCC and VIN thresholds have been exceeded, and power-on-resets are released, the control circuitry waits for an EN high signal from one or multiple external components. In the case of multiple EN signals, they are typically logically tied together. Power-on-reset is a signal that is generated by specially designed circuitry as the bias supply comes up into operational range, and is a signal that is used to reset all logic gates to a known, predictable state. Power-on-reset function is well understood by those skilled in the art.

Referring to FIG. 4A and FIG. 4B, the EN signal, circled in FIG. 4A triggers internal control logic to generate a series of ‘dummy’ PWM cycles, which propagate to the UGATEx and LGATEx outputs in the timing diagram shown in FIG. 4B, where ‘x’ corresponds to a number of the target FET pair (e.g., UgFET1 302, LgFET1 304, UgFET2 306, LgFET2 308). These cycles are referred to as “dummy” cycles because they are internally generated (not received from the external PWM controller) and they are used to quickly charge up the coupling capacitors (e.g., CUG1, CLG1, CUG2, CLG2) and are not intended to regulate an output voltage. The ‘dummy’ cycles exercise the FET gates, causing charging of the coupling capacitors CUG1, CLG1, CUG2, CLG2 which then allow the switching transistors to be held off and the input switch to be turned on. A number of ‘dummy’ PWM cycles that may be propagated may vary with the design of the converter components. In various embodiments, the cycle count is 1, 2, 4, 10, 20, 50, or more cycles. A typical count may be 16 cycles. Once these cycles have completed, FIG. 4B illustrates the negative charge pumps 314 being enabled to maintain the D-mode FETs in an off-state (tristate) until the VIN switch is turned on and externally generated PWM signals are permitted to control switch operation. See FIG. 4B timing diagram as an illustration of the start-up sequence. The described components and their operation embody a dual path gate drive; an AC-coupled path for high speed switching, and a second DC path for maintaining off-state gate bias.

A timer may be used to allow sufficient delay for the input switch, VIN Switch, to turn on. The VIN switch's turn-on is controlled, occurring gradually to avoid high inrush currents from developing, as indicated by the slope in the wave pattern associated with the VDC 227 (VIN switch output). When the VIN switch timer expires, the control circuitry allows externally generated voltage control signals, PWMx, to propagate through the Control Logic to the Gate Driver Control circuit. PWM signals are propagated to the upper and lower gate drives to control the on or off states of the FETs of the half bridge switch configuration, thereby regulating the converter output.

In various embodiments, while receiving PWM signals to control the half-bridge circuit, a watchdog timer may detect an absence of PWM signals for a predetermined period. Since the operation under PWM signals recharges the gate capacitors, and since the gates of the FETs leak charge commensurate to the voltages applied to their terminals, the depletion of these capacitors (CUG1, CLG1, CUG2, CLG2) may allow the D-mode devices to inadvertently switch to an unintended state. For example, a D-mode n-channel FET may inadvertently turn-on when the capacitor charge is depleted.

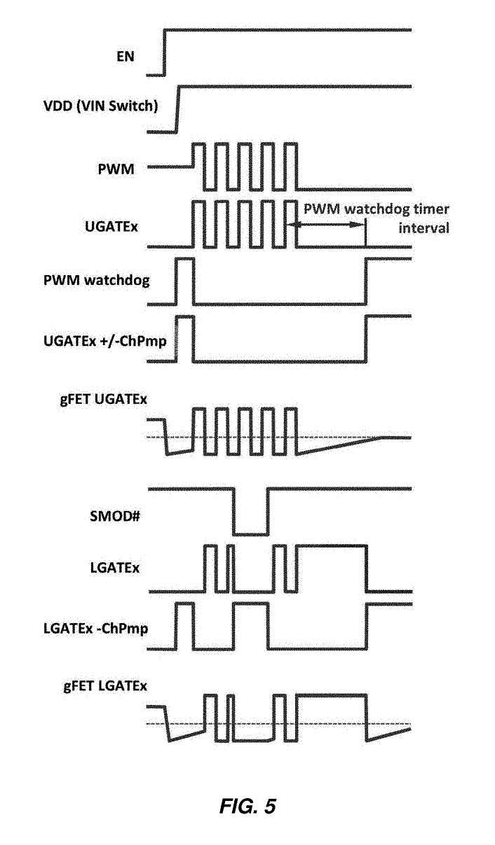

FIG. 5 is an example timing diagram that illustrates the response of the circuit of FIG. 3 to changes in PWM and SMOD input signals. The driver outputs follow the PWM input signal, where a PWM high turns on the upper FET switch and a PWM low turns on the lower FET switch. A tri-stated PWM keeps both upper and lower transistor switches off.

As shown in FIG. 5, activity of the watchdog timer in response to the absence of a low-to-high PWM transition over a pre-determined time interval causes the PWM watchdog signal to go high, and the control circuitry to enable the upper negative charge pumps. Somewhat similarly, SMOD# assertion, asynchronous to PWM operation, turns off the lower power switch driver and enables the respective phase's lower negative charge pump (when there is one SMOD# input per phase).

In some embodiments, the gate driver circuit shown in FIG. 3 may be integrated on the same semiconductor substrate with the FET transistors of the half-bridge circuit when compatible materials and fabrication processes are used. For example, a GaAs-based driver or a smaller sub-section of it may be integrated with GaAs-based upper/lower transistors (e.g., UgFET1 302, LgFET1 304, UgFET2 306, LgFET2 308) on the same substrate. In other situations where materials and fabrication techniques are inadequate for full integration, package level integration may suffice. In some embodiments a hybrid integrated circuit (HIC) may be formed, wherein a portion of the components are integrated on a single substrate, and the remaining portion of components are integrated at the package level (e.g. on a common substrate). For example, integrating a Si FET driver matched with GaAs-based Upper/Lower FETs may be accomplished at the package level.

In some embodiments, an asynchronous converter may be emulated using the gate drive controller to control the state of the lower transistor (e.g., LgFET1 304, LgFET2 308) in response to a skip mode input signal, SMOD. In these embodiments, activating SMOD turns off the lower gate drive output, keeping the lower device off while SMOD is active. Any positive inductor current passes through a lower integrated freewheeling Schottky diode. The circuit layout of FIG. 3 illustrates freewheeling Schottky diodes DBDL1 and DBDL2. This may be different from true zero-crossing diode emulation, which is a mode of low-current operation. In order to keep the lower devices (e.g., LgFET1 304, LgFET2 308) off for extended periods of time, the lower drivers' negative charge pumps are made active while SMOD is asserted.

FIG. 3 also illustrates two pairs of half-bridge converters (i.e., UgFET1 302 paired with LgFET1 304, and UgFET2 306 paired with LgFET2 308) that can be applied to two separate output voltage domains. Various other embodiments may include additional pairs of half-bridge converter circuits that can be used to add additional phases. The additional half-bridge circuits may be embodied separately or integrated.

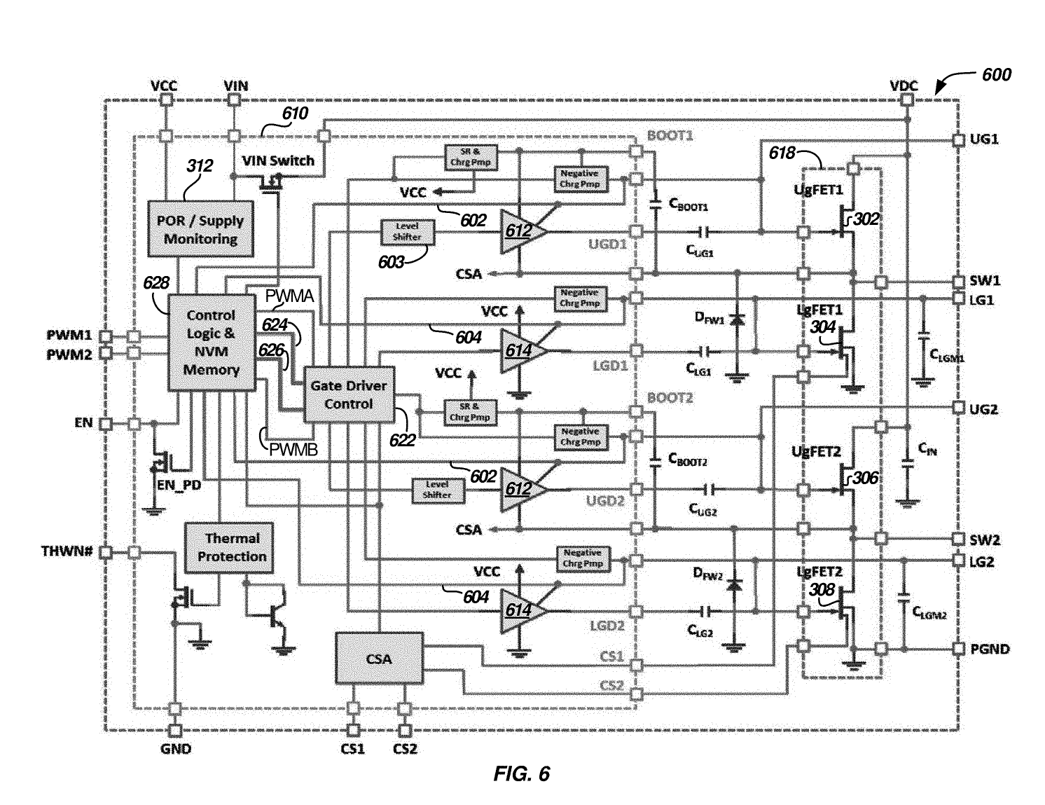

FIG. 6 illustrates an alternative dual phase DC-DC converter power stage circuit 600 comprising deadtime control for power switching transistors in accordance with aspects of the technology. The power stage circuit 600 of FIG. 6 includes a dual phase gate driver 610, a power switch stage 618, (variously referred to elsewhere herein as switches, power switches, and switch elements) and various interface components described elsewhere herein.

FIG. 6 differs from FIG. 3 in that various signal lines in FIG. 3 are omitted in FIG. 6, including SMOD1#, SMOD2#, LED, and TED. The dual phase driver 610 of FIG. 6 differs from the dual phase driver 310 of FIG. 3 in that various internal signals have been added to the driver 610, including upper gate sense 602, lower gate sense 604, leading edge address bus 624, and trailing edge address bus 626. While the gate driver 610 is illustrated as driving two switching transistor pairs, first switch pair 302/304 (UgFET1 302 and LgFET1 304) and second switch pair 306/308, (UgFET2 306 and LgFET2 308) the gate driver 610 may be configured for driving more or fewer switching transistor pairs.

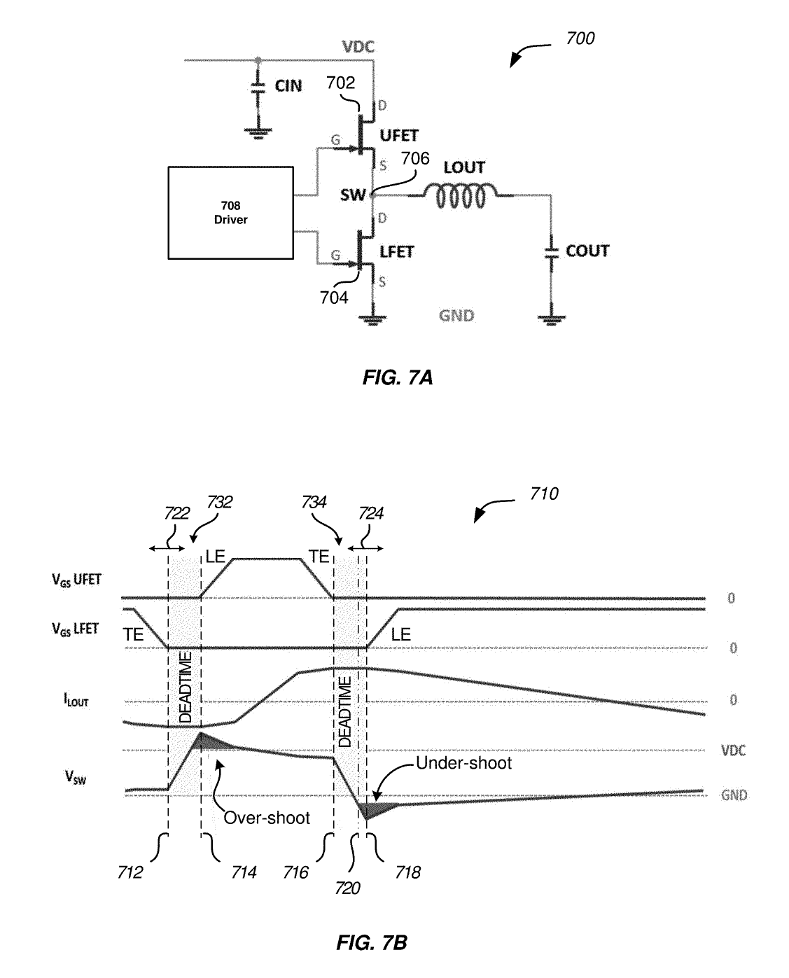

FIG. 7A illustrates a high level diagram of a half-bridge synchronous buck based power switching converter (or power converter) 700 of FIG. 6. FIG. 7A is highly simplified for purposes of illustrating a timing diagram of FIG. 7B. The power converter 700 of FIG. 7A includes two switches 702 and 704 arranged in series that may represent switches 302 and 304, respectively, in FIG. 3. The two series switches 702 and 704 may also represent switches UgFET1 302 and LgFET1 304, respectively, of the power switch stage 618 in FIG. 6. The driver 708 may represent driver 610 of FIG. 6. The output node 706 of the switching converter, corresponding to the similar-functionality of output node SW1 (and similarly output node SW2) of FIG. 6, is applied to a load including an inductor LOUT and a capacitor COUT, not illustrated in FIG. 6

The two series switches, upper switch 702 and lower switch 704 may be described as straddling a power supply capable of sourcing very large magnitude currents. Some form of dead-time control is desirable in such a power converter. Should the series switches 702 and 704 conduct simultaneously, very large currents can be developed through these switches. This current is often referred to as shoot-through. Shoot-through may substantially decrease the conversion efficiency of the power converter 700. Shoot-through can also lead to the destruction of the switch elements 702 and/or 704 due to excessive current conduction.

Conversely, lack of conduction through either switch 702 or 704 while the current through the magnetic storage element LOUT is not zero, may cause overshoot and/or undershoot, or conduction through circuit elements not primarily intended for such purpose (body or catch/freewheeling diodes), which may lead to similar loss of conversion efficiency. The overshoot/undershoot condition can also lead to voltage stresses that may exceed the breakdown ratings of the various circuit elements in a circuit such as power converter 700. As a result, this overshoot/undershoot condition may lead to possible damage of the power converter 700. Deadtime control may be used to prevent shoot-through while reducing overshoot/undershoot and improving the power converter's operating efficiency.

FIG. 7B is an exemplary timing diagram 710 illustrating deadtime associated with a Pulse Width Modulated (PWM) signal applied to the driver 708 of the half-bridge based power switching converter 700 of FIG. 7A. An upper switch control voltage “V_{GS}UFET” represents a voltage responsive to a PWM pulse applied by the driver 708 to the gate to source (G-S) junction of the upper switch 702. A lower switch control voltage “V_{GS}LFET” represents a voltage responsive to the PWM pulse similarly applied by the driver 708 to the G-S junction of the lower switch 704. A current I_{LOUT} represents a current through the load inductor LOUT, and a switch voltage V_{SW} represents a voltage output by the power switch converter 700 at the switch node 706.

A first or PWM leading edge deadtime 732 in FIG. 7B occurs between the trailing edge of lower FET voltage V_{GS}LFET, at time 712 and the leading edge of the upper voltage V_{GS}LFET at time 714. A second or PWM trailing edge deadtime 734 occurs between the trailing edge of upper voltage V_{GS}LFET at time 716 and the leading edge of lower voltage V_{GS}LFET at time 718. An amount of delay 722 of the PWM leading edge determines when the trailing edge of lower voltage V_{GS}LFET occurs. Similarly, an amount of delay 724 of the PWM trailing edge determines when the leading edge of lower voltage V_{GS}LFET occurs.

As may be observed in FIG. 7B, decreasing the delay 724 for the leading edge of lower voltage V_{GS}LFET to time 720 may decrease the second deadtime 734 and decrease the undershoot at the PWM trailing edge. Conversely, increasing the delay 724 for the leading edge of lower voltage V_{GS}LFET may increase the second deadtime 734 and increase the undershoot.

Similarly, increasing the delay 722 for the trailing edge of lower voltage V_{GS}LFET such that the trailing edge occurs after time 712 and closer to time 714 serves to decrease the deadtime and decrease the overshoot at the PWM leading edge. Conversely, decreasing the delay 722 for the trailing edge of lower voltage V_{GS}LFET such that the trailing edge occurs before time 712 and further from time 714 serves to increase the deadtime 732 and increase the overshoot at the PWM leading edge.

Various approaches have been developed and employed for controlling deadtime. Traditionally, a fixed deadtime approach builds in a rather large fixed amount of deadtime which results in safe, but not necessarily efficient, operation over the range of applications and parameter variations for the expected combinations of power train components (driver, switches and any associated circuit elements). When setting a traditional fixed deadtime, part-to-part variations are estimated, and estimates are used to build in some conservative margin to avoid shoot-through throughout the expected range of parameters and component variations. As a result, the fixed deadtime approach, while safe, is never optimal for most implementations, in both static or dynamic output voltage or load operation.

Another approach includes self-adaptive schemes that have been developed. In a self-adaptive scheme, the deadtime is continuously adjusted during normal PWM operation of the circuit. The continuous adjustments are based on circuit voltage measurements that are used to gauge the state of conduction of the switches (UFET 702 and LFET 704). These adaptive schemes may yield acceptable performance under static conditions. However, these adaptive schemes fail to deliver the ideal deadtime under dynamic operation, when the output voltage (VOUT) is changed or the output load (e.g., LOUT) rapidly varies. Under such conditions, the current through a magnetic storage element, such as load inductor LOUT can change polarity rapidly and, in turn, affect behavior of the switch node 706 and the resulting sensed voltage. This leads to inefficient deadtime settings.

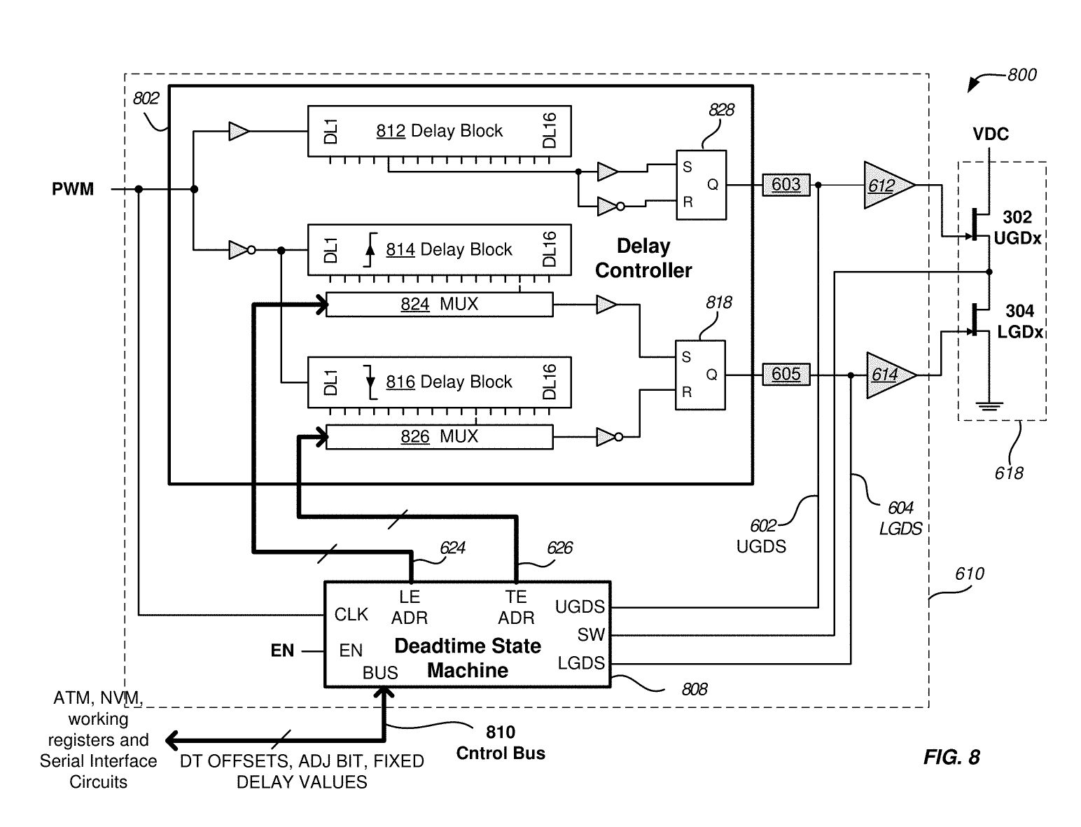

FIG. 8 illustrates an exemplary deadtime circuit 800 for deadtime testing, trimming, storage, and control for switching transistors 618 of FIG. 6. The deadtime circuit 800 of FIG. 8 includes delay controller 802 and a deadtime state machine (DSM) 808. The delay controller 802 includes an upper delay block 812, a lower leading edge delay block 814, and a lower trailing edge delay block 816. Delay controller 802 further includes a leading edge multiplexer (MUX) 824 addressably coupled to delay taps of the leading edge delay block 814, a trailing edge MUX 826 addressably coupled to delay taps of the trailing edge delay block 816, and conditioning logic, such as a latch 818 coupled to the outputs of MUX 824 and MUX 826 and optional latch 828 coupled to the output of delay block 812. For simplicity, FIG. 8 illustrates tapping a fixed delay in the delay block 812.

Optionally, the upper gate path is similarly adjustable using an addressable multiplexer controlled by the control bus 810 passed through a similar interface via the deadtime state machine 808. The upper gate path may be described as a path of the PWM signal through various circuits including the upper delay block 812, the latch 828, the driver 612 and other devices to the gate of the gate of upper switch 302. The lower gate path may be described as a path of the PWM signal through various circuits including the delay blocks 814 and 816, MUXs 824 and 826, latch 818, driver 614 and other devices to the gate of the gate of lower switch 304. The upper gate path delay setting may not be subject to adjustment during adjustment lower gate path for purposes of deadtime determination. The upper gate path delay may be used to provide a positive and negative range of adjustment within an operational range of the lower gate path.

The delay controller 802 and DSM 808 are configured to select the first deadtime 732 and second deadtime 734 as further described. The output of a driver 612 is derived from a PWM signal after being delayed by the upper delay block 812 and other devices in the upper gate path. The amount of the delay is tap selectable. The delay controller receives the PWM and buffers it to the upper delay block 812. A tap of the upper delay block 812 may be coupled to the driver 612 via a latch 828, a buffer, and/or a level shifter 603. The output of the driver 612 may be coupled to gate of an upper switch (e.g., UgFET1 302 or UgFET2 306) of the circuit 600 in FIG. 6. The coupled tap may be selected during fabrication or post fabrication. While a delay block 812 is illustrated as being used for delaying the PWM signal in FIG. 8, a single, fixed delay circuit may be fabricated using, e.g. an RC circuit configured to provide a predetermined amount of delay, with or without a buffer.

The leading and trailing edges output by the driver 614 may be derived from the PWM signal after being delayed by the leading edge delay block 814 and trailing edge delay block 816, respectively. The leading edge of the PWM may be delayed by the delay block 814 and the trailing edge of the PWM signal may be delayed by the delay block 816. The PWM signal may be coupled to the lower leading edge delay block 814 and the lower trailing edge delay block 816. In some embodiments the PWM signal is coupled to the delay blocks 814 and 816 via an inverter, as illustrated in FIG. 8. Alternatively, output of the latch 818 or output of MUX 824 and MUX 826 may be inverted. The MUX 824 may select a delay tap of the leading edge delay block 814 and couple the delayed PWM signal to the latch 818, e.g., at a set (S) input. The MUX 826 may select a delay tap of the trailing edge delay block 816 and couple the delayed PWM signal to the latch 818, e.g., at a reset (R) input.

The leading and trailing edge delay taps of FIG. 8 are addressable. Means for loading leading and trailing edge addresses include the control bus 810, the DSM 808, the leading and trailing edge address busses 624 and 626, and MUXs 824 and 826. A leading edge delay address may be coupled from the DSM 808 to the MUX 824 via the leading edge address bus 624. The leading edge delay address may be used by the MUX 824 to select a delay tap of the leading edge delay block 814. A trailing edge delay address may be coupled from the DSM 808 to the MUX 826 via the trailing edge address bus 626. The trailing edge delay address may be used by the MUX 826 to select a delay tap of the trailing edge delay block 816. The PWM signal may be used by the DSM 808 to increment or decrement the leading and trailing taps (addresses) via the leading address bus 624 and trailing address bus 626, respectively. Alternatively logic circuits within the DSM 808 are used to step through leading and/or trailing edge addresses. In some embodiments, a synchronous divide-by-N (where N is an integer) lower frequency variant of the PWM signal is used by the DSM 808 to increment or decrement the leading and trailing taps (addresses). Selecting the PWM leading edge delay using the lower trailing edge address allows selection and adjustment of the first deadtime 732. Similarly, selecting the PWM trailing edge delay using the lower leading edge address allows selection and adjustment of the second deadtime 734. During operation of the circuit 600, the leading and trailing edge addresses may be selected from values stored in non-volatile memory (NVM). During testing of the circuit 600, the leading and trailing edge addresses may be loaded externally and/or generated by the DSM 808. While a number of components are described in the deadtime circuit 800, more or fewer components may be used to control deadtimes. In some embodiments, testing includes dropping into PWM mode while stepping through the leading and/or trailing edge addresses, and then enabling test mode again to store deadtime values in NVM.

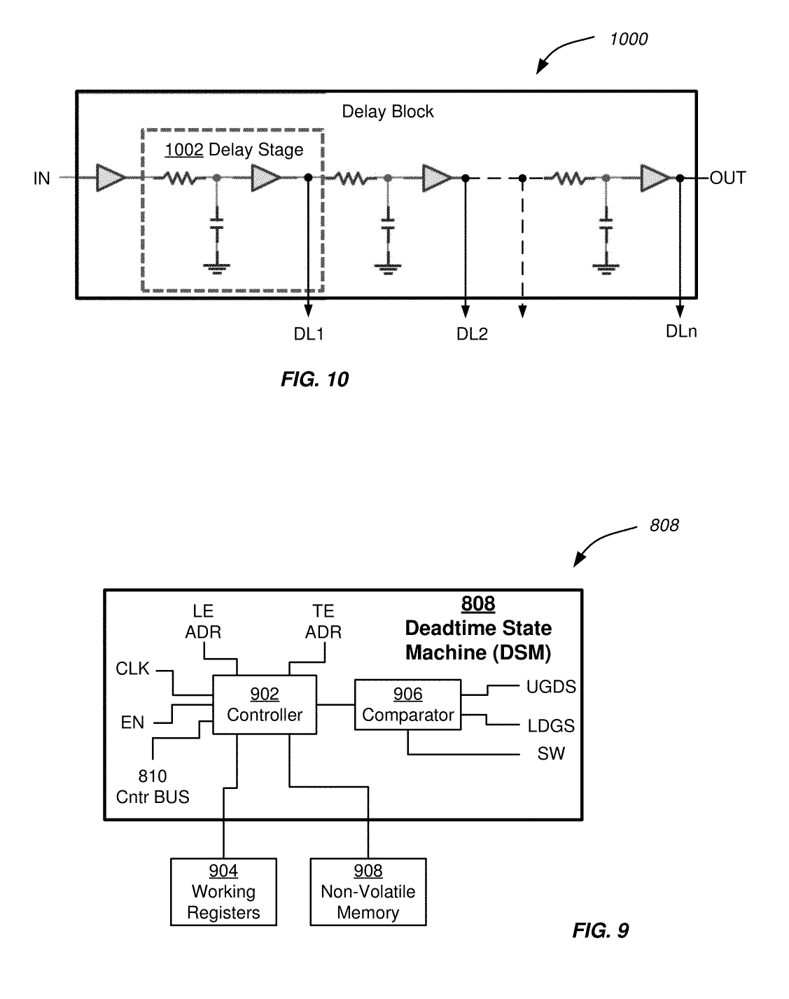

FIG. 9 illustrates details for the DSM 808 of FIG. 8. The DSM 808 includes a controller 902 and a comparator 906. The controller 902 communicates with working registers 904 and/or NVM 908. In some embodiments, the working registers 904 and/or NVM 908 are part of the DSM 808. More or fewer components may be implemented in the DSM 808.

The controller 902 is configured to receive data from the control bus 810, clock signals, comparator 906 (UGDS signals, and LGDS signals), and use the received signals to determine leading and trailing edge delays in the form of leading and trailing edge addresses to place on the leading and trailing address busses 624 and 626, respectively. In various embodiments, additional signals transferred via the control bus 810 include deadtime offsets/targets for the self-adjust circuitry for both channels, deadtime settings for setting the deadtimes manually, deadtime settings to be written to the NVM using the automated test equipment, bandgap test and trim bits, lock bit, configuration settings, and/or the like. In various embodiments, configuration settings include OVP enable or disable, selection of one of multiple built-in threshold settings for various other functions, enabling or disabling OCP functionality, and/or the like.

The control bus 810 may be a serial bus. In some embodiments, the PWM1 and PWM 2 signals of circuit 600 in FIG. 6 may be used as the control bus 810. For example, the EN signal of FIG. 6 may be pulled negative or substantially above its normal high state to place the DSM 808 into test mode (instead of normal mode) and indicate that the PWM1 signal is a clock and PWM2 is a data control bus 810 for the DSM 808. The control bus 810 may address circuits and register/memory locations within one or more channels using an address that has a sufficient number of bits to address each channel DSM 808 and the various locations and registers within the DSM 808.

The working registers 904 are configured to store various values or settings used by various components of the driver 610, including the controller 902, during normal operation and/or during test mode operation. Examples of values and settings stored in the working registers 904 include offsets/target deadtimes for determining deadtime leading and trailing addresses, deadtime leading or trailing edge MUX addresses, as well as configuration and trim settings related to other driver functionality (e.g., normal operation).

The NVM 908 is configured to store the content of the working registers 904 as well as other data in addition to data related to the functionality of the driver. These settings/data may be permanently stored in the NVM 908. The leading and trailing edge address may be coupled to MUX 824 and 826, respective for use during normal operation of the circuit 600. Various types of memory that can be used for NVM include various types of non-volatile memory technology including fuses, PROM, EPROM, EEPROM, FRAM, charge storage cell-based memories, and/or the like.

The comparator 906 may include means in the form of logic and/or analog circuits for determining a deadtime and determining if the deadtime is less than a target deadtime. The comparator 906 is configured to receive the UGD sense (UGDS) 602 from the driver 612 and LGD sense (LGDS) 604 from the driver 614. The comparator 906 may use logic and/or analog comparator circuits to compare the trailing edge time of LGDS 604 to the leading edge time of the UGDS 602 to calculate the first deadtime 732. The comparator 906 may compare the trailing edge time of the UGDS 602 to the leading edge time of the LGDS 604 to calculate the second deadtime 734.

The comparator 906 may further include logic to compare the first deadtime 732 to the target first deadtime stored in the working registers 904 and inform the controller 902 if the first deadtime 732 is greater or less than the target first deadtime. The comparator 906 may further use logic to compare the second deadtime 734 to the target second deadtime stored in the working registers 904 and inform the controller 902 if the second deadtime 734 is greater or less than the target second deadtime. The controller 902 may use the indication to increment or decrement the values for leading edge addresses and trailing edge addresses to multiplexers 824 and 826, respectively, in order to converge toward the target/offset deadtime values provided in working register 904.

In some embodiments, means for progressively decreasing deadtime output by stepping through leading and/or trailing addresses include a clocked counter. A working register may be a counter or may be used to load a counter in the DSM 808. The clock may be some integer multiple (e.g., 1, 2, 3, 4, 5, 6, 7, 8, 16, 32, 128, 256, etc.) of PWM pulse pulses. In some embodiments, the clock is generated using logic components within the DSM 808.

Once having converged, the addresses to multiplexers 824 and 826 may be permanently stored in NVM 908. Means for storing a deadtime value in NVM include programs and/or logic in the controller 902, and/or software in automated test equipment (ATM). While a number of components are described and used in the DSM 808, more or fewer components may be implemented and used to perform functions of the DSM 808.

In test mode operation, the controller 902 may receive initial leading and trailing edge delays during test mode and place those values in locations in the working register 904 corresponding to the leading and trailing address. The controller may also place target leading and trailing edge addresses in corresponding working registers 904. The controller 902 may place the initial leading and trailing edge address values that are in the working registers 904 onto the leading and trailing edge busses 624 and 626, respectively. The initial leading and trailing edge addresses may be selected to maximize the respective deadtimes. In some embodiments the controller 902 places either the maximum or minimum address on the leading and trailing edge addresses to maximize the deadtimes.

The controller 902 may then operate in a step mode to generate a series of new leading edge and/or trailing edge addresses for the working registers 904. Responsive to the comparator 906 based on a comparison of the target deadtimes to measured deadtime at the comparator 906, the controller 902 may stop generating addresses and load the NVM.

In normal operation, the controller 902 may load fixed leading and trailing edge addresses from NVM 908 to locations in the working register 904 corresponding to the leading and trailing address. The controller may then place the fixed leading and trailing address values in the working registers 904 on busses 624 and 626, respectively, and initiate start-up in normal mode. In some embodiments, the controller 902 fetches the fixed leading and trailing edge values from the NVM 908 and outputs the values to the leading and trailing edge address buses 624 and 626, respectively.

FIG. 10 illustrates details for delay blocks 1000 used in FIG. 8. For example, FIG. 10 illustrates details for delay blocks 812, 814, and/or 816 of FIG. 8. The delay block 1000 includes multiple delay stages arrayed in series. Each delay stage is configured to delay an input (IN) signal (e.g., PWM in FIG. 8) by a predetermined amount. A delay stage 1002 comprises series of one or more passive (RC) and/or active components, logic gates, buffers, current sources, comparators, latches, and/or inverters. The delay stage 1002 of FIG. 10 illustrates an example of a passive RC delay circuit, a buffer, and a tap DL1 for outputting the delayed input signal IN; however, other active and/or passive components may be used for the delay stage 1002. In various embodiments, delay blocks have 1, 2, 4, 8, 16, 32, or more delay stages. While a number of components are described and used in the delay block 1000, more or fewer components may be implemented and used to perform functions of the delay block 1000.

While a tap of the upper delay block 812 is illustrated in FIG. 8 as being hardwired (e.g., selected using fusible links), an upper delay multiplexer (not illustrated) may be used to select a delay tap in a manner similar to the delay block 814 and MUX 824. An upper address bus (not illustrated) may be used to provide tap addresses from the working registers 904 and/or NVM 908 to the upper multiplexer, in a manner similar to the address busses 624 and 626. An adjustable/addressable upper delay block 812 may be used instead of illustrated hardwiring, in order to position the leading and trailing edges of the V_{GS}LFET within adjustment range of the leading and trailing edges of the V_{GS}LFET.

For convenience and understanding, the delay controller 802 and components illustrated therein are described as being part of the gate driver control 622. Also, the DSM 808, working registers 904, NVM 908, and components illustrated within the DSM 808 are described as being part of the Control Logic & NVM Memory 628. However, for purposes of fabrication of a device and use of the deadtime circuit 800 within the driver 610, various components of the delay controller 802 and DSM 808 may be implemented as a part of either the control logic & NVM 628 or the gate driver control 622, or may be distributed elsewhere on the driver 610 according to design choices for implementing the driver 610.

More generally, the gate driver control 622, control logic & NVM 628, delay controller 802, DSM 808 may be considered to be conceptual blocks of digital logic, analog devices, active, and/or passive components for the purpose of understanding and illustration of the gate driver 610. Individual components of these conceptual blocks may be distributed in various locations throughout the gate driver 610, and those locations within the gate driver 610 may be selected according to design practices and requirements for performance of the gate driver 610.

Generally a target deadtime may be calculated or otherwise determined for a configuration of upper FET circuitry, lower FET circuitry, driver, interconnect parasitics, and packaging. Application of a very tight, fixed target deadtime may be useful throughout a range of both static and dynamic operation. However, the desired optimal deadtime may not be achieved in a device due to various factors. These factors include part to part variations during fabrication (process related), variations between design performance and actual performance of particular switch elements of the switch stage (modeling related), parasitics of a particular driver paired with the switch stage (packaging/embedding related), and switching performance of the driver (largely related to sizing of switch elements 618, e.g., for use with various FETs sized for different output current).

During an initial test trim procedure, the power switch stage 618 of the circuit 600 may be operated under controlled, steady-state PWM operation. An algorithm including a fine-step digital adaptive deadtime scheme may be used (e.g., by the DSM 808) to automatically determine a setting (e.g., for MUX 824 and 826) that will provide an optimal deadtime for switch elements (e.g., UFET 302 and LFET 304) of the power switch stage 618, the driver 610 as combined with the power switch stage 618, as well as the switching performance of the driver 610, all in the given packaging environment surrounding all these components. Once a digital setting for the optimal deadtime is determined, the digital setting may be stored into built-in non-volatile memory (e.g., NVM 908) onboard the driver 610.

Once the desired settings are stored in NVM 908, the stored, fixed settings may be provided from the NVM 908 to MUXs 824 and 826 when the driver 610 is biased for normal operation. The stored settings in the NVM 908 may be used as fixed deadtime settings throughout the lifetime operation of the driver 610 and the power stage it is then on a part of.

Advantageously, the initial determination of deadtime settings for the target deadtime takes into account part-to-part variations of both the driver and the switches, variations between design performance and actual performance of particular switch elements, parasitics of a particular driver paired with the switch stage, and switching performance of the driver related to sizing of components, as well as effects of onboard circuitry used for determining the fixed settings to store in NVM. Thus, benefits of a very tight, fixed deadtime setting may be realized throughout a range of both static and dynamic operation.

The delay controller 802 of deadtime circuit 800 may provide a value for deadtime selection that is expected to achieve the target deadtime. The value may be provided from a digital register location (e.g., working register 904). The target deadtime value may be written to a location in the working registers 904 using an external source (e.g., Automated Test Equipment used in the trim procedure). Deadtime selection circuitry in the delay controller 802 (e.g. MUXs 824 and 826) may incorporate a sufficient range of adjustability to provide for the pairing of various power switches and various packaging implementations, which may require slight adjustments to achieve target deadtimes.

Consider that during a first-of-kind evaluation of the driver 610 against design target specifications, the evaluation would be performed using the gate driver 610 packaged in a standalone configuration, physically separated from the power switches 618. This would result in increased parasitics, which would affect the determination of settings for optimal deadtime. That is, the deadtimes achieved in using the standalone package during first-of-kind evaluation would not reliably match deadtimes resulting from the combination of the gate driver 610 heterogeneously packaged with the power switches 618, e.g., due to increased parasitics.

An exemplary approach to determining a desired deadtime begins with selecting a tap in the delay block that results in a conservatively large deadtime, and then monotonically stepping through the taps towards the minimum achievable deadtime. To step through the taps, the settings may be incremented (or decremented) after a number of PWM switching cycles, e.g., using a counter. The counter may be an up/down counter. In various embodiments, the number of cycles in the steps is 1, 2, 3, 4, 5, 6, 8, 16, 32, or more. The number of cycles in a step may be selected according to the speed of the circuits making the determination (e.g., the comparator 906 used comparing the measured deadtime against the target deadtime).

Once the measured deadtime matches or crosses the target deadtime, the digital circuitry controlling the algorithm may stop incrementing the delay setting. A measured deadtime that is less than the target deadtime may be used to indicate that the target deadtime has been achieved. The comparator 906 may be used for measuring the deadtime and comparing the measured deadtime to the target deadtime. A value may be generated (e.g., by the controller 902) based on the end delay setting (delay setting at which the algorithm stopped). In some embodiments, the generated delay values are the LE MUX 824 and/or the TE MUX 826 addresses. The delay values may then be burned into NVM 908 for the deadtime setting. For example, the delay value burned into the NVM 908 may be the end delay setting, or the end delay setting minus 1, 2, 3 or more increments (the delay settings before the algorithm stopped) or delay settings plus 1, 2, 3 or more increments. In some embodiments the end delay setting and/or delay value may be communicated externally for use by external test equipment involved in the test/trim of the driver. The externally communicated end delay setting may be used for later storage of a delay setting into the driver NVM 908. The external test equipment may burn the delay values into the NVM 908. In some embodiments, the external test equipment uses the end delay setting to calculate delay values to be burned into NVM 908 and/or burn the calculated delay values into the NVM 908.

As may be seen in the FIGS. 7 and 8, the desired deadtime for matching the target deadtime may be determined for both switching edges of the PWM (i.e., PWM leading edge and PWM trailing edge). The range of adjustability for a desired deadtime determination may span a finite non-overlapping range in addition to a shorter overlapping range. Generally, overlap in device conduction is the very definition of shoot-through and something the deadtime circuit 800 is designed to avoid. However, in some cases a small amount of overlap in the outputs of the gate control can benefit deadtime adjustment. This may be the case in applications where the sizes (and consequently the gate charges) of the upper and lower output switches (e.g., switches UgFET1 302 and LgFET1 304) are mismatched. Such mismatch may occur in devices and/or circuits optimized for either low or high steady-state duty cycle operation.

Multiple instances of the deadtime circuit 800 may be disposed in gate drivers. Each instance of the deadtime circuit 800 may be specific to a switch pair and used to determine deadtime settings during test operation for that switch pair, and to load fixed deadtime settings from NVM during normal operation, for that switch pair. For example, the DC-DC converter power stage circuit 600 of FIG. 6 includes two switch pairs 302/304 and 306/308. Two instances of the deadtime circuit 800 may disposed in the gate driver 610 of circuit 600, and each switch pair may be served by a separate instance of the deadtime circuit 800. However, more or fewer instances of the deadtime circuit 800 may disposed in the gate driver 610 of circuit 600 to serve more or fewer switch pairs.

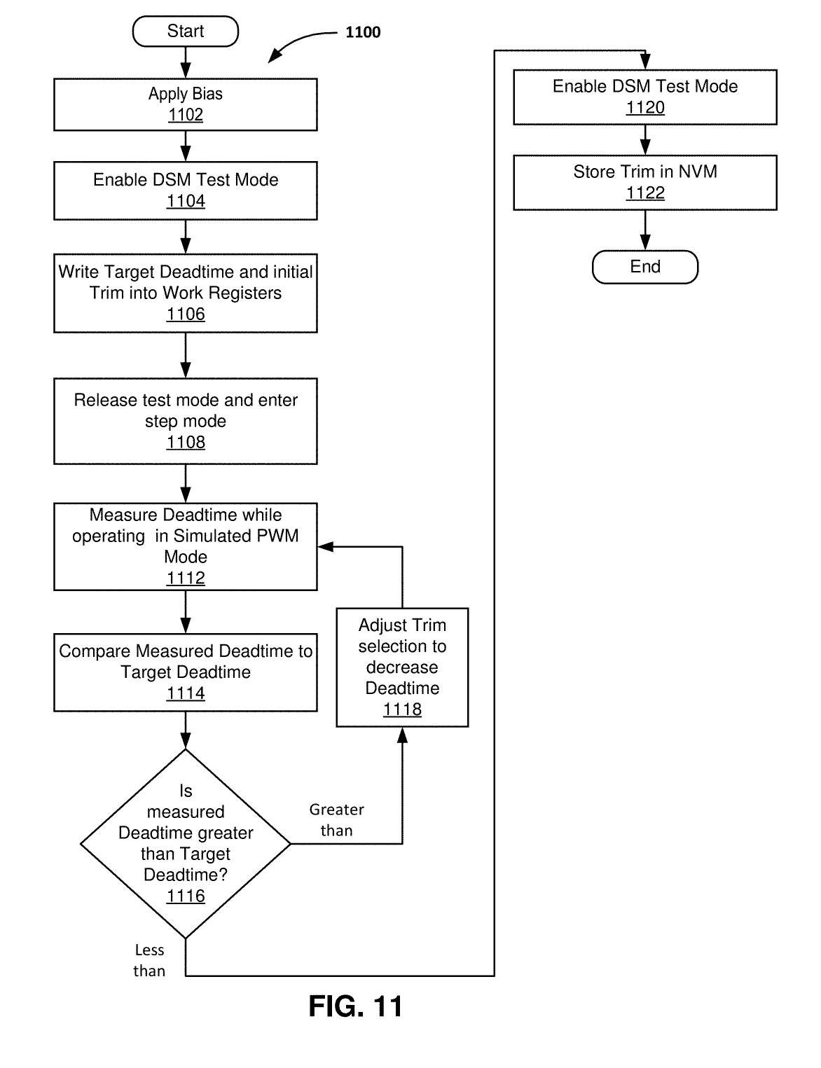

FIG. 11 is a flowchart 1100 illustrating an exemplary method for selecting a deadtime in accordance with aspects of the technology. In step 1102 bias is applied to the circuit 600. Voltage may be applied at the bias supply voltage, VCC, and the power supply voltage, VIN.

At step 1104, the DSM 808 and self-adjust deadtime method are enabled. The DSM test mode may be enabled. For example, the EN signal of FIG. 6 may be pulled substantially above its normal high state to place the DSM 808 into test mode (instead of normal mode), which indicates to the DSM 808 that the PWM1 signal is to be used a clock and PWM2 is to be used as a serial bus for the DSM 808 during the test mode. In some embodiments, the EN signal is pulled negative to enable test mode. Releasing the test mode (dropping out of test mode) allows the EN signal to return to its normal high or low state and may place the deadtime circuit 800 in a step mode or a normal or PWM mode.

At step 1106, the target deadtimes and initial tap selections are written into work registers. For example, the target deadtime and initial tap selection may be serially clocked, using the PWM, into the DSM 808 via control bus 810 and controller 802. The DSM 808 may place the target deadtime and initial tap selection data into appropriate working registers 904, e.g. using the controller 902. In some embodiments, MUXs 824 and 826 are initialized to the longest, respective, deadtimes (e.g., setting or resetting appropriate registers in the working registers 904) without writing initial tap selections to working registers 904.

Other data may also be written into the working registers 904 at this time. For example, if the bandgap requires adjustment, the bandgap trim may be written to the working register 904. Thus, circuits that utilize the bandgap trim, such as various current sources dependent on the bandgap value, can operate at nominal parameters. In some embodiments, a bit is set to bypass the normal dummy cycles and go directly into turning on the input switch and allowing PWM signals to pass through the driver and output switches, once dropping out of test mode.

Also at step 1106, initial tap selection values may be applied to the multiplexers using the working registers 904 to present tap values to respective delay taps. For example, the DSM 808 may apply tap selection values to MUXs 824 and 826 via the leading and trailing edge address busses 624 and 626, respectively. The controller 902 may use these busses to apply values from the working registers 904. In some embodiments, values in working registers 904 are presented as tap addresses directly to the MUXs 824 and 826 via the leading and trailing edge address busses 624 and 626, respectively. In general, the system may begin at a tap corresponding to the longest deadtime and walk back towards the shortest deadtime tap with each pass through step 1112. The initial tap values may be used for selecting a delay tap other than the longest delay time to shorten the determination process.

At step 1108, the DSM 808 may drop out of test mode to operate in a step mode for a number of cycles in order to allow an adjust deadtime routine to converge toward a desired deadtime. The DSM 808 drops out of test mode at step 1108 until the desired deadtime is identified. The working registers 904 are maintained at step 1108. The PWM signals may be used during the step mode as normal PWM signals while measuring the deadtime as the DSM 808 walks from longer deadtimes towards the shorter deadtimes. In some embodiments, a separate serial bus interface, which is not superimposed on signals with other functionality, is used to allow the driver 610 to operate in PWM mode while in test mode. While the PWM signals are used for a clock and a communication bus during transfer of data to the DSM 808 in test mode, at step 1108, the PWM signals revert back to being used as normal PWM signals for deadtime trim during a number of cycles of the step mode while retaining the work registers content. The DSM 808 then walks through the leading and/or trailing edge addresses in subsequent steps to change the delays as described below.

At step 1112 the deadtime is measured while operating in step mode using the PWM as a normal PWM signal. In general, the system may begin at a tap corresponding to the longest deadtime and walk back towards the shortest deadtime tap with each pass through step 1112. On the first pass through step 1112, initial tap selections have been applied to the multiplexers. With each subsequent pass, the tap selections applied to MUX 824 and/or MUX 826 are changed to decrease the deadtimes. In some embodiments, the DSM 808 applies tap selection values to MUXs 824 and 826 via the leading and trailing edge address busses 624 and 626, respectively. The initial tap values may be selected to provide other than the longest delay time. This may serve to shorten the determination process, at the cost of adding more volatile memory locations. Another cost/risk is that the initial shorter deadtime setting could cause shoot-thru and damage a part if too aggressive. At each subsequent pass through step 1118 a different leading and/or trailing address may be applied to MUXs 824 and 826 using the controller 902 or via working registers directly to the multiplexers.

For example, the PWM signals may be used for a number of cycles sufficient for bracketing a deadtime output that best matches the target deadtime. The comparator 906 may receive the UGD sense (UGDS) 602 and LGD sense (LGDS) 604 signals. If the first PWM deadtime is under test, the comparator 906 may compare the trailing edge time of the LGDS 604 to the leading edge time of the UGDS 602 to calculate the first PWM deadtime 732. For example, the comparator 906 may capture clock cycles between occurrence of the trailing edge of the LGDS 604 and the leading edge of the UGDS 602 to calculate the first PWM deadtime 732. If the second deadtime is under test, the comparator 906 may similarly compare the trailing edge time of the UGDS 602 to the leading edge time of the LGDS 604 to calculate the second PWM deadtime 734.

At step 1114, the measured deadtime is compared to the target deadtime to detect a crossover. For the initial deadtime value, the measured deadtime will be longer or greater than the target deadtime. Upon crossover, the measured deadtime will be the about equal to, or shorter (less) than the target deadtime. The comparison may be made after a delay or settling time.

If the first deadtime 732 is under test, the comparator 906 may compare the first deadtime 732 to the target first deadtime stored in the working registers 904 and inform the controller 902 if the first deadtime 732 is greater or less than the target first deadtime. If the second deadtime is under test, the comparator 906 may compare the second deadtime 734 to the target second deadtime stored in the working registers 904 and inform the controller 902 if the second deadtime 734 is greater or less than the target second deadtime. These comparisons may be performed using logic comparators and/or software executed using the controller 902.

At step 1116, if the deadtime under test is greater than the target deadtime the method branches to step 1118. Alternatively, if the deadtime under test is less than the target deadtime crossover has been detected and the method branches to step 1120.

At step 1118, the method adjusts the tap selection to decrease the deadtime. For example, if the first PWM deadtime 732 is under test, the controller 902 may increment the delay tap value in the working registers 904 for MUX 826 to increase the trailing edge delay time and decrease the PWM leading edge deadtime. If the second PWM deadtime 734 is under test, the controller 902 may decrement the delay tap value in the working registers 904 for MUX 824 to decrease the leading edge delay time and decrease the trailing edge PWM deadtime.

The new delay values may be applied to the multiplexers by the working registers 904 directly at step 1118 to select respective delay taps. For example, tap delay values in the working registers may be presented directly to the MUXs 824 and 826 via the leading and trailing edge address bus 624 and 626, respectively. In some embodiments, the controller 902 applies delay values from the working registers 904 to the MUXs 824 and 826 via these busses. Upon applying new tap delay values to MUX 824 and/or MUX 826, step 1118 then returns to step 1112 for another pass.

At step 1120, DSM test mode is enabled as in step 1104, while retaining the current content of the working registers 904 from step 1116. This places the DSM 808 in a state for reading the optimal deadtime settings that were obtained in steps 1112-1118, and writing them to NVM 908, or saving them for later writing to the NVM 908.

At step 1122, the method stores a delay value in non-volatile memory. For example, if the first deadtime 732 is under test, the controller 902 may store the delay tap value that is in the working registers 904 for MUX 824 into a register in the NVM 908 corresponding to the fixed delay tap for the leading edge deadtime. Alternatively a previous or next delay tap value is stored in NVM 908. In some embodiments, the controller 902 calculates a delay value corresponding to the delay tap value that is in the working registers 904 for MUX 824 for storage in the NVM 908

If the second deadtime 734 is under test, the controller 902 may store the delay tap value that is in the working registers 904 for MUX 826 into a register in the NVM 908 corresponding to the fixed delay tap for the trailing edge deadtime. Alternatively a previous or next delay tap value is stored in NVM 908. In some embodiments, the controller 902 calculates a delay value corresponding to the delay tap value that is in the working registers 904 for MUX 826 for storage in the NVM 908

In some embodiments, both the first and second deadtimes are under test simultaneously. Instead of stopping after step 1122, the method may flag the first or second deadtime no longer being under test and branch to step 1118 to continue until the other deadtime test is no longer under test.

In some embodiments, the tap settings are passed over the control bus 810 to the ATE for calculations of delay values and later storage of calculated delay values in the NVM 908. The exported tap settings may be used for loading a batch of devices 600, for example based on a statistically significant number of devices from the batch returning the same tap values to the ATE in response to testing.

While a number of steps are described in method 1100, namely steps 1102-1122, more or fewer steps may be used to perform the method 1100 of FIG. 11. In some embodiments, the DSM 808 or portions of the DSM 808 are duplicated in the driver 610 such that the deadtime trim may be performed in parallel on two or more channels. Thus, not only can both edges of a PWM be tested set at the same time, but all the channels of a device may be tested and/or set simultaneously.

In some embodiments, one or more working registers 904 used for the LE or TE addresses are counters configured to count up or down as appropriate for progressively decreasing deadtimes. The counters may be up/down counters. The counters may be clocked by internal logic such as the comparator 906 and/or controller 902 as a result of a determination by the comparator 906 that a deadtime is not less than its target deadtime. The working registers 904 used for the LE or TE addresses may be coupled directly to MUX 824 and/or MUX 826.

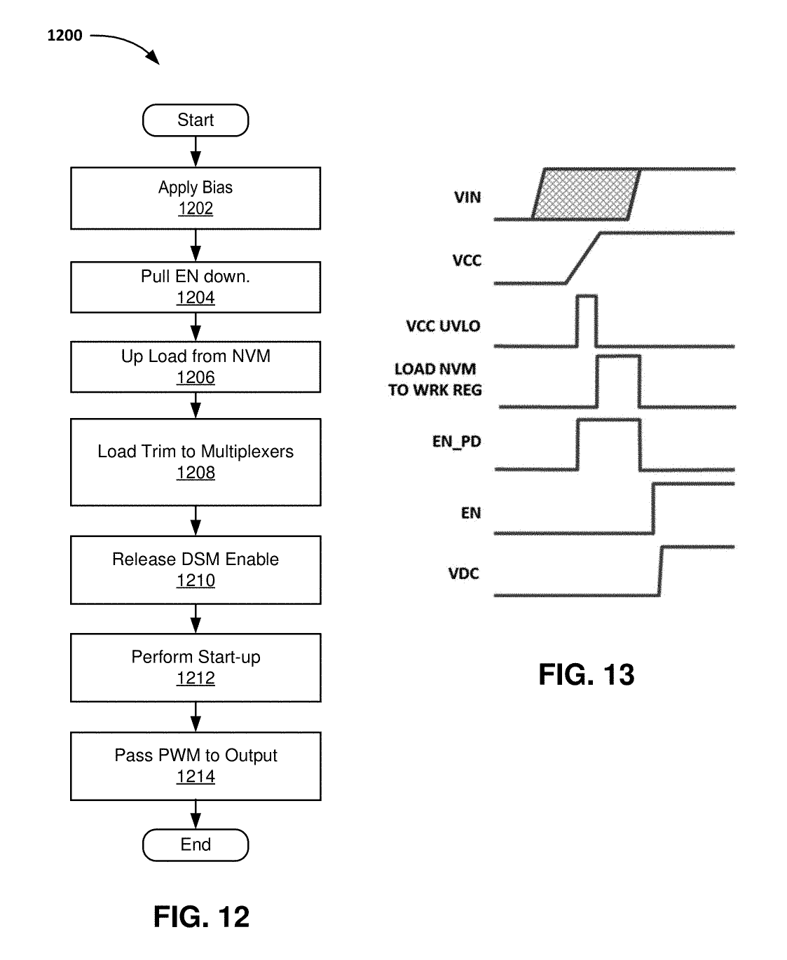

FIG. 12 is a flowchart 1200 illustrating an exemplary method for a startup routine in accordance with aspects of the technology. FIG. 13 is an exemplary timing diagram that illustrates a start-up sequence in accordance with aspects of the technology. FIG. 13 differs from FIG. 4A in that the signals VCC Under Voltage Lock Out (VCC UVLO) and LOAD NVM TO WRK REG are added, and low to high transitions in the EN and VCC signals occur later in FIG. 13 than in FIG. 4A. FIG. 12 is described below with reference to the signals and timing illustrated in FIG. 13.

One goal of the startup routine 1200 is to load the fixed values for the deadtimes from non-volatile memory 908 before placing the power switches 618 into normal operation mode, responsive to the PWM signals. During a normal start-up, the PWM signals may be ignored until uploading of the various parameters from NVM is complete and the driver 610 has completed the start-up routine. Once the conditions for normal operation are established during startup sequence, the power switches 618 are operated normally in response to the PWM signals.

In step 1202 bias is applied to the circuit 600. Voltage may be applied at the bias supply voltage, VCC, and the power supply voltage, VIN.

At step 1204, as circuits come alive and UVLO is asserted, the EN signal is pulled down. The EN_PD (enable pull down) may be used to do this. The EN_PD signal goes high with the transition of VCC UVLO from low to high. The VCC UVLO signal is generated from monitoring power rail voltages to determine if they are in range. VCC UVLO goes low when the power rails are in their desired range. This is to prevent the power switches 618 from operating until the power voltages are within the correct range and values, such as the deadtimes, are loaded.

At step 1206, Data from the NVM 908 is loaded to working registers (LOAD NVM TO WRK REG). This may be initiated by the VCC UVLO de-assertion, as illustrated in FIG. 13. Data from the NVM 908 is used to provide the various parameters, deadtime settings included, to be used by the driver 610 in normal operation. For example, fixed deadtime values for the leading and trailing edge delays may be loaded from NVM 908 to working registers 904 corresponding to the leading and trailing edge addresses, respectively. Values for other parameters may be uploaded from the NVM 908. In some embodiments, the DSM 808 loads the deadtime values. Alternatively, other logic is used for loading the deadtime values.

At step 1208, delay values are loaded to the multiplexers. For example, the leading edge address is loaded from a corresponding working register 904 to the MUX 824 via the leading edge address bus 624 for adjusting delay of the leading edge at driver 614. Similarly, the trailing edge address is loaded from a corresponding working register 904 to the MUX 826 via the trailing edge address bus 626, for adjusting delay of the trailing edge at driver 614. In some embodiments, the values in the NVM 908 are uploaded directly. Steps 1206 and 1208 may occur during the period that the LOAD NVM TO WRK REG is high.

At step 1210, the EN_PD is released. Release of the EN_PD signal happens after completion of loading the working registers NVM 908. This includes loading the deadtime values. Release of the EN_PD signal is also conditioned on the voltages being within operational range. In FIG. 13, the EN_PD goes low releasing the EN signal once both the LOAD NVM TO WRK REG and the VCC UVLO are low. Release of the EN signal may initiate the startup procedure.

At step 1212, a startup procedure is performed. The start-up procedure is illustrated and described elsewhere here with respect to FIGS. 3, 4A, 4B and 13.

At step 1214, the PWM signals that have been delayed by fixed amount using the deadtime values uploaded from NVM 908 are passed to the output of the gate driver 610 upon completion of the startup procedure.

While a number of steps are described in method 1200, namely steps 1202-1214, more or fewer steps may be used to perform the method 1200 of FIG. 12.

The above description is illustrative and not restrictive. This patent describes in detail various embodiments and implementations of the present invention and the present invention is open to additional embodiments and implementations, further modifications, and alternative constructions. There is no intention in this patent to limit the invention to the particular embodiments and implementations disclosed; on the contrary, this patent is intended to cover all modifications, equivalents and alternative embodiments and implementations that fall within the scope of the claims. Moreover, embodiments illustrated in the figures may be used in various combinations. Any limitations of the invention should, therefore, be determined not with reference to the above description, but instead should be determined with reference to the appended claims along with their full scope of equivalents.

What is claimed is:

1. A deadtime circuit comprising:
an upper delay block coupled to a PWM signal and a tap of the upper delay block coupled to an upper gate driver;
a lower leading edge (LE) delay block having a plurality of LE delay taps and coupled to an inverted PWM signal line;
a lower LE multiplexer coupled to the plurality of LE delay taps of the lower LE delay block and configured to select one of the plurality of the LE delay taps responsive to a lower LE address for output to a lower LE delay signal line;
a lower trailing edge (TE) delay block having a plurality of delay taps and coupled to the inverted PWM signal line;
a lower TE multiplexer coupled to the plurality of delay taps of the lower TE delay block and configured to select one of the plurality of the TE delay taps responsive to a lower TE address for output to a lower TE delay signal line;
a latch, inputs of the latch coupled to the lower LE delay signal line and the lower TE delay signal line, an output coupled to a lower gate driver; and
a deadtime state machine configured to:
output a lower LE address to the lower LE multiplexer for selecting a LE delay tap,
output a lower TE address to the lower TE multiplexer for selecting a LE delay tap,
receive an upper gate drive sense signal from output of the upper gate driver,
receive a lower gate drive sense signal from output of the lower gate driver,
calculate a LE deadtime based on the upper and lower gate drive sense signals, and
increase the LE address if the LE deadtime is greater than a target deadtime, or store the LE address in non-volatile memory (NVM) if the LE deadtime is not greater than the target LE deadtime.

2. The deadtime circuit of claim 1, wherein the deadtime state machine is further configured to:
place the deadtime circuit in test mode for receiving the TE address and LE address;
place the deadtime circuit in a step mode to receive the upper and lower gate drive sense signals; and
place the deadtime circuit in test mode to store the TE address in NVM.

3. The deadtime circuit of claim 1, wherein the deadtime state machine is further configured to:
output a lower TE address to the lower TE multiplexer for selecting a TE delay tap;
output a lower TE address to the lower TE multiplexer for selecting a TE delay tap;
receive an upper gate drive sense signal from output of the upper gate driver;
receive a lower gate drive sense signal from output of the lower gate driver;
calculate a TE deadtime based on the upper and lower gate drive sense signals; and
increase the TE address if the TE deadtime is greater than a target deadtime, or store the TE address in non-volatile memory (NVM) if the TE deadtime is not greater than the target TE deadtime.

4. The deadtime circuit of claim 1, wherein the upper delay block is adjustable responsive to an upper address.

5. The deadtime circuit of claim 1, further comprising an upper multiplexer coupled to a plurality of delay taps of the upper delay block and configured to select the tap of the upper delay block coupled to an upper gate driver responsive to an upper address.

6. A deadtime adjustment system comprising:
an upper gate driver coupled to a delayed Pulse Width Modulated (PWM) signal and an upper gate of a DC-DC converter power stage circuit;
a first adjustable delay circuit coupled to the PWM signal and configured to output a first delayed PWM signal responsive to a first delay address;
a second adjustable delay circuit coupled to the PWM signal and configured to output a second delayed PWM signal responsive to a second delay address;
a latch configured to receive the first and second delayed PWM signals and output a lower PWM signal via a lower gate driver to a lower gate of the DC-DC converter power stage circuit; and
a deadtime state machine including circuits and logic programmed to:
operate in a step mode comprising:
applying the first address from a working register to the first adjustable delay circuit,
receiving an upper gate drive sense signal derived from the upper gate driver and a lower gate drive sense signal derived from the lower gate driver,
measuring a first deadtime using the upper and lower gate drive sense signals, and
if the first deadtime is greater than a target first deadtime, increment or decrement the first address in the working register to decrease the first deadtime, and repeat the step mode using the decreased first deadtime, or
if the first deadtime is not greater than the target first edge deadtime, store the first address in non-volatile memory (NVM), and exit the step mode; and
operate in a test mode comprising:
receiving values for working registers including an initial first address, an initial second address, a target first edge deadtime, and a target second edge deadtime, and
outputting a fixed first address from NVM to the first addressable delay circuit.

7. The deadtime adjustment system of claim 6, wherein the step mode further comprises:
outputting the second address from a working register to the second adjustable delay circuit;
receiving an upper gate drive sense signal derived from the upper gate driver and a lower gate drive sense signal derived from the lower gate driver;
measuring a second deadtime using the upper and lower gate drive sense signals; and
if the second deadtime is greater than a target second deadtime, increment or decrement the second address in the working register to decrease the second deadtime, and repeat the step mode; or
if the second deadtime is not greater than the target second edge deadtime, store the second address in non-volatile memory (NVM), and exit the step mode.

8. The deadtime adjustment system of claim 7, wherein the PWM signal is coupled to the upper gate driver via an upper delay circuit.

9. The deadtime adjustment system of claim 8, wherein upper delay circuit is adjustable.

10. The deadtime adjustment system of claim 8, wherein upper delay circuit is adjustable responsive to an upper delay address received from the deadtime state machine.

11. The deadtime adjustment system of claim 6, wherein NVM is a circuit in the deadtime state machine.

12. A method for adjusting deadtime in a DC-DC converter power stage circuit, the method comprising:
placing the DC-DC converter power stage circuit in test mode;
loading a delay address to a delay circuit that produces a deadtime output from the deadtime circuit greater than a target deadtime;
placing the DC-DC converter power stage circuit in step mode;
stepping through delay addresses to progressively reduce the deadtime output of the deadtime circuit until the deadtime output of the deadtime circuit is less than the target deadtime; and
placing the DC-DC converter power stage circuit in test mode;
storing a deadtime value corresponding to the currently loaded delay address in non-volatile memory of the DC-DC converter power stage circuit.

13. The method of claim 12, further comprising:
exporting the currently loaded delay address to an automated test machine; and
receiving from the automated test machine a deadtime value based on the delay address and an instruction to store the delay value in the non-volatile memory.

14. The method of claim 12, wherein stepping through delay addresses comprises at each step:
placing the DC-DC converter power stage circuit in PWM mode;
operating the DC-DC converter power stage circuit in PWM mode for a predetermined number of PWM cycles;
determining deadtime output of the deadtime circuit for the step;
comparing the determined deadtime output of the deadtime circuit to the target deadtime; and
placing the DC-DC converter power stage circuit in test mode.

15. The method of claim 12, further comprising:
loading the stored deadtime value to the delay address of the deadtime circuit; and
initializing a signal to initiate a normal operation mode of the DC-DC converter power stage circuit.

16. The method of claim 12, further comprising:
initializing a signal to initiate a normal operation mode of the DC-DC converter power stage circuit;
loading the stored deadtime value to the delay address of the deadtime circuit;
initializing a signal to initiate a startup mode of the DC-DC converter power stage circuit; and
upon completion of the startup mode initializing a signal to initiate a normal operation mode of the DC-DC converter power stage circuit.

17. A system for adjusting deadtime of a DC-DC converter power stage circuit, the method comprising:
a delay circuit coupled to a PWM signal and a lower gate of the DC-DC converter power stage circuit;
means for loading an initial delay address to the delay circuit that corresponds to a maximum deadtime output from the delay circuit while operating in test mode;
means for progressively decreasing deadtime output from the delay circuit by stepping through delay addresses loaded to the delay circuit while operating in a step mode;
means for determining for each progressive loaded deadtime address if the deadtime output of the delay circuit is less than a target deadtime;
non-volatile memory (NVM) for storing a fixed deadtime value corresponding to the delay address loaded for the deadtime output determined to be less than the target deadtime; and
means for loading the fixed deadtime value from NVM to the delay circuit for operation in PWM mode.

18. The system of claim 17, wherein the means for loading a delay address includes a working register.

18. The system of claim 18, wherein the working register is a counter.

20. The system of claim 17, wherein the fixed deadtime value stored in the NVM is the delay address that is first loaded for the deadtime output determined to be less than the target deadtime.
